(19) United States
(12) Patent Application Publication
(10) Pub. No.: US 2009/0217965 A1
(43) Pub. Date: Sep. 3, 2009

(54) APPARATUS AND METHOD FOR ENHANCED SOLAR POWER GENERATION AND MAXIMUM POWER POINT TRACKING

(76) Inventors: Roger A. Dougal, Columbia, SC (US); Lijun Gao, West Columbia, SC (US); Shengyi Liu, Columbia, SC (US); Albena Iotova, Columbia, SC (US)

Correspondence Address: DORITY & MANNING, P.A., POST OFFICE BOX 1449, GREENVILLE, SC, 29602-1449, US

(21) Appl. No.: 12/280,696

(22) PCT Filed: Apr. 20, 2007
(86) PCT No.: PCT/US07/09672

§ 371 Date: Jan. 20, 2009

Related U.S. Application Data
(60) Provisional application No. 60/793,784, filed on Apr. 21, 2006.
(60) Provisional application No. 60/833,092, filed on Jul. 25, 2006.

(51) Int. Cl. H01L 31/042

(52) U.S. Cl. 136/244

(57) ABSTRACT

Disclosed is an apparatus and methodology for generating operating power for various desired applications using solar energy. A solar array is formed using a small number of solar cells connected in series to form a string of solar cells and then connecting multiple strings in parallel. Unlike conventional solar arrays, no bypass diodes are incorporated into the array. A power converter is coupled to the array to boost output voltage to a level sufficient to operate the desired application. The power converter may be operated independently or based on output levels of the array, the material from which the solar cells of the array are constructed and the operating temperature of the array or combinations thereof.

### CROSS-REFERENCE TO RELATED APPLICATION

This application claims the benefit of U.S. Provisional Applications Ser. No. 60/793,784, filed on Apr. 21, 2006, and No. 60/833,092, Jul. 25, 2006, both of which are assigned to the assignee of the present application.

### STATEMENT OF GOVERNMENT INTEREST

The present subject matter was developed under Grant N0014-0301-0952 from the Office of Naval Research. The government retains certain rights in this subject matter.

### FIELD OF THE INVENTION

The present subject matter relates to a solar power generation apparatus employing a methodology for maximum power point (MPP) tracking. More particularly the present subject matter relates to a solar power generation apparatus capable of maximizing the power generation of a solar array for portable and mobile applications that are often subject to partially shading or continuously changing shadow conditions.

### BACKGROUND OF INVENTION

Photovoltaic (PV) cells have been widely used in portable applications such as solar jackets and solar bags to generate convenient electricity. Unlike standing solar arrays mounted outdoors, portable solar arrays incorporated into solar jackets or bags may be subject to partial shading and/or continuously changing shadow conditions. For example, when carrying a solar jacket through a city, illumination condition on the surface of the solar array changes continuously and the intensity is non-uniform across the surface due to shadows of trees, vehicles, and buildings, as well as due to change of orientation of the array relative to the sun. Partially shaded cells generate a certain amount of energy that can not be used by classical designs where bypass diodes are used.

Typically, a single solar cell produces an output voltage around 0.5 V, and a plurality of cells is conventionally connected in series to provide higher voltage levels. As shown in FIG. 1, solar cells 10 are conventionally connected in series to form a string 22 in order to obtain the desired output voltage. Bypass diodes 23 are added to bypass mismatched or shaded cells. As illustrated in FIG. 1, bypass diodes 23 may be configured to bypass several diodes as opposed to providing a bypass diode for each individual solar cell. In solar arrays, individual cells are generally connected in series forming a string 22 to obtain the desired voltage, while plural such strings 22 are connected in parallel to obtain a desired current producing capacity for the array.

In an exemplary arrangement, for a nominal 12 volt Si solar array charging system, about 36 cells are connected in series to produce a 12 volt output. Usually, diodes are placed across groups of cells, e.g. 10-15 cells per diode instead of one bypass diode per cell to lower the cost. Cells connected in series with bypass diodes have been proven to be effective in many PV applications, such as remote PV power stations and PV residential power systems, where sunlight is uniform across the solar array surface with only very few number of cells possibly shaded. This arrangement, however, does not work as well for portable solar. arrays, because the operation of portable solar arrays is constantly under complex illumination conditions due to user's random movement and varying shadow conditions.

Solar arrays in portable and mobile applications are often subject to partially shading or continuously changing shadow conditions. These complex irradiance conditions cause two problems for the solar arrays using the conventional configurations. First, partially shaded cells generate a certain amount of energy but that energy cannot be collected by the widely used designs where bypass diodes are used, thus this part of the energy is wasted. This problem is not a significant problem in those high-voltage stationary systems that do not have obstructions. It is a significant problem, however, in low voltage systems for portable and mobile applications where partial shading occurs frequently and quite a fraction of cells may be partially shaded. For example, carrying a solar jacket through a city, the illumination condition on the surface of the solar array changes continuously and the intensity is non-uniform across the surface due to shadows of trees, vehicles, and buildings, as well as due to change of orientation of the array relative to the sun. Second, continuously changing shadow conditions increase the difficulty of the maximum power point tracking. It is very hard to identify the global maximum because multiple maximum power points exist and their values are rapidly fluctuating corresponding to shadow conditions. Even if at some instants one can know where the global maximum is, it would probably change before it was possible to shift the maximum power point tracker to that operating point. In other words, very fast tracking speeds and good control stability are particularly required for a maximum power point tracker to work well under this situation.

Presently available maximum power point tracking methods generally work well under reasonably slow and smooth changing illumination conditions. On the other hand, even if the maximum power tracking works well, the energy generated by partially shaded cells can not be collected, while this part of energy could be comparatively large especially when quite a number of cells are partially shaded.

In view of the identified problems with the prior art, it would be advantageous to develop an optimum array configuration in terms of cell connections to maximize the array power generation under changing shading and illumination conditions.

### SUMMARY OF INVENTION

The present subject matter recognizes and addresses the disadvantages of prior art constructions and methods. Accordingly, it is an object of the present subject matter to provide a solar array configuration with respect to optimum solar cell size and connections to maximize the power generation of the solar array under partially shading or continuously changing shadow conditions.

As the terminal voltage of the solar array using the configuration provided by the present subject matter will be relatively low and cannot be directly used by general applications, it is a further object of the present subject matter to boost the terminal voltage of the solar array to voltage levels capable of providing general application operating power.

Yet still a further object of the present subject matter is to provide a solar array configuration with respect to optimum solar cell size and connections to maximize the power generation of the solar array under partially shading or continuously changing shadow conditions.

It is yet another object of the present subject matter to provide a maximum power point (MPP) tracking methodology based on the solar array configuration, and to integrate and implement the method into an associated power converter.

To address the above objects, the present subject matter provides a solar power generation apparatus corresponding to a solar array which is formed by connecting a very limited number of solar cells in series to form a string and connecting a plurality of solar cell strings in parallel; and a power converter which is connected to said solar array to boost the solar array terminal voltage to a desired level to match the target application requirement. A solar array constructed in accordance with the present technology is capable of maximizing the power generation of each solar cell under partially shading or continuously changing shadow conditions.

Also provided by the present subject matter is a maximum power point tracking method for a solar power generation apparatus having a solar array which is formed by connecting a very limited number of solar cells in series to form a string and connecting a plurality of solar cell strings in parallel without using bypass diodes and a power converter which is connected to said solar array to boost the solar array terminal voltage to a desired level to match the target application requirement, said method comprising the control of the solar array terminal voltage to follow the prescribed reference values that are determined by the solar cell manufacturing material and the solar panel operation temperatures.

Additional objects and advantages of the present subject matter are set forth in, or will be apparent to, those of ordinary skill in the art from the detailed description herein. Also, it should be further appreciated that modifications and variations to the specifically illustrated, referred and discussed features and elements hereof may be practiced in various embodiments and uses of the invention without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the present subject matter may include various combinations or configurations of presently disclosed features, steps, or elements, or their equivalents (including combinations of features, parts, or steps or configurations thereof not expressly shown in the figures or stated in the detailed description of such figures). Additional embodiments of the present subject matter, not necessarily expressed in the summarized section, may include and incorporate various combinations of aspects of features, components, or steps referenced in the summarized objects above, and/or other features, components, or steps as otherwise discussed in this application. Those of ordinary skill in the art will better appreciate the features and aspects of such embodiments, and others, upon review of the remainder of the specification.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a block diagram showing a conventional solar panel with multiple cells in series to form a string to obtain desire voltage level;

FIG. 2 is a block diagram showing an experimental solar power generation system in accordance with an exemplary embodiment of the present subject matter;

FIG. 3 is a graph showing output power versus cell current of a solar cell at different levels of irradiation intensity;

FIG. 4 is a graph showing output power versus terminal voltage of a solar cell at different levels of irradiation intensity;

FIG. 5 is a graph showing output power versus terminal voltage of a solar cell at different temperatures;

FIG. 6 is a graph showing the temperature effectiveness on power versus terminal voltage characteristics of a solar cell;

FIG. 7 is a chart comparing power generation between a conventional system and a system constructed in accordance with the present technology;

FIG. 8 is a table showing experimental conditions associated with the chart of FIG. 7;

FIG. 9 is a block diagram showing an experimental solar power generation system in accordance with an exemplary embodiment of the present subject matter;

FIG. 10 is a graph showing experimental output power versus terminal voltage characteristics of a solar cell array under different shading conditions;

FIG. 11 is a graph showing voltage and current levels produced during a 130 second experimental test;

FIG. 12 is a graph showing power generation produced during a 130 second experimental test;

FIG. 13 illustrates an exemplary analysis configuration of a conventional solar array system;

FIG. 14 illustrates an exemplary analysis configuration of a solar array constructed in accordance with the present subject matter;

FIG. 15 is a graph illustrating power generation of the solar array illustrated in FIG. 13 as a function of load;

FIG. 16 illustrates a power output comparison between the simulated conventional system and a simulation of a system constructed in accordance with the present subject matter;

FIG. 17 illustrates solar array output voltage and current during simulation; and

FIG. 18 illustrates solar array power generation during simulation.

Repeat use of reference characters throughout the present specification and appended drawings is intended to represent same or analogous features or elements of the invention.

### DETAILED DESCRIPTION OF THE PREFERRED EMBODIMENTS

As discussed in the Summary of the Invention section, the present subject matter is particularly concerned with optimization of solar cell size and connections to maximize power generation of the solar array under partially shading or continuously changing shadow conditions.

Selected combinations of aspects of the disclosed technology correspond to a plurality of different embodiments of the present invention. It should be noted that each of the exemplary embodiments presented and discussed herein should not insinuate limitations of the present subject matter. Features or steps illustrated or described as part of one embodiment may be used in combination with aspects of another embodiment to yield yet further embodiments. Additionally, certain features may be interchanged with similar devices or features not expressly mentioned which perform the same or similar function.

Reference will now be made in detail to the presently preferred embodiments of the subject solar power generation apparatus. Referring now to the drawings, FIG. 2 illustrates a block diagram of an experimental solar power generation system in accordance with an exemplary embodiment of the present subject matter. As may be seen in FIG. 2, a limited number of solar cells 110 may be connected in series to provide a relatively short string 111 of such series connected solar cells 110. In exemplary configurations solar cells 110 numbering between one and three may be employed to produce strings 111. The general concept, however, broadly encompasses the fact that the voltage level produced by the series connected cells, regardless of the number connected in series, is less than that required to operate the target external device. Thus the addition, in accordance with the present subject matter, of the DC to DC converter 120 is advantageous to achieve a desired operating voltage.

After coupling such small numbers of solar cells 110 in series to form strings 111, multiple such strings 111 may then be connected in parallel to provide a desired power generating capability. An output line 112 from such parallel connected strings 111 may then be coupled to a DC to DC converter 120 configured to boost the relatively low output voltage level from the parallel connected strings 111 to a voltage level sufficient to charge storage device 130 and operate an external device. It should be appreciated that, in accordance with the present subject matter, no bypass diodes such as bypass diodes 23 previously used and discussed above with reference to FIG. l are used or required with the presently disclosed subject matter.

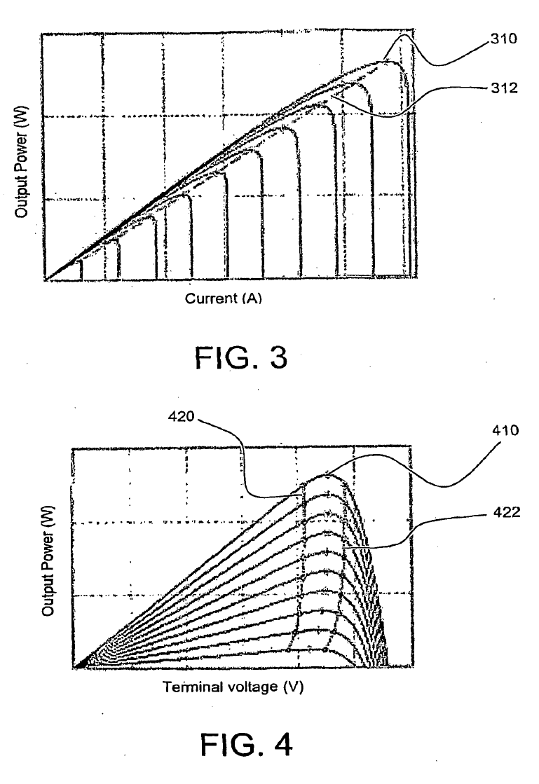

FIG. 3 illustrates exemplary output power curves of a solar cell as a function of current under ten irradiance levels from 100 W/m² to 1000 W/m² with a step change of 100 W/m² at 300 K. The maximum power points are indicated with star marks, representatively illustrated by star mark 310. It can be seen that, from FIG. 3, the maximum power points of the cell are almost linearly proportional to the cell current as illustrated by dashed line 312. Therefore, it is impossible to find a single value of current that makes all the cells work at (or near) their maximum power points.

FIG. 4 shows the output power as a function of voltage at ten irradiance levels. The maximum power points are indicated with star marks, representatively illustrated by star mark 410. The two nearly vertical lines 420, 422 with circle marks define the region in which the solar cells function at 95% of the maximum possible power generation at the different irradiance levels. It can be seen from FIG. 4 that the maximum power points at different irradiance levels occur at nearly a common voltage. In addition, the curves have rather broad peaks and the peak power is not very sensitive to voltage; therefore, operating slightly off of the voltage corresponding to the maximum power only reduces the power supplied by a very small percentage.

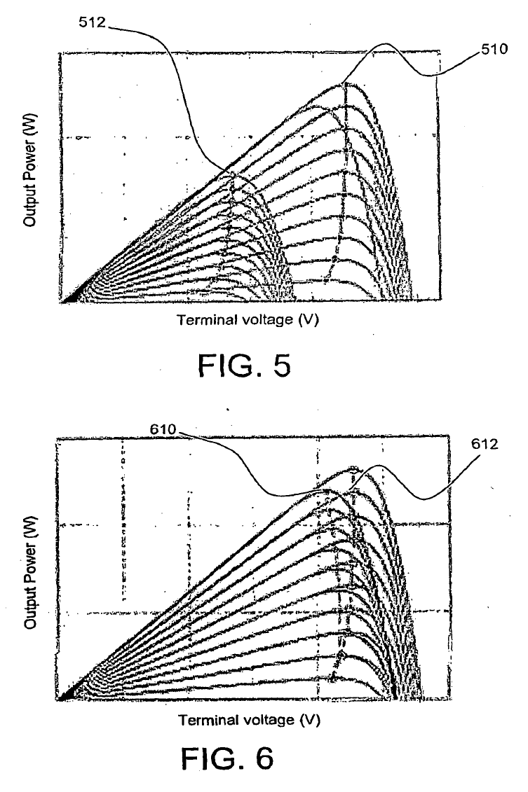

With reference now to FIG. 5, there is illustrated a graph showing output power versus terminal voltage of a solar cell at different temperatures. The operation characteristics of a solar cell are affected by temperature. As shown in FIG. 5, the lines with star marks, representatively star mark 510, from top to bottom, denote the P-V curves at 300 K from 1000 W/m² to 100 W/m², and the lines with circle marks, representatively circle mark 512, denote the P-V curves at 380 K. The temperature of 380 K is far too hot for a wearable array, but still that temperature might be reached in a small stationary array under some conditions, especially if it were insulated from wind.

It can be seen in FIG. 5 that, at a given irradiance level, the voltage value corresponding to the maximum power point decreases as the temperature increases. Therefore, if there are large temperature differences (e.g., 80 K) among different solar cells within the array, the voltage values corresponding to the maximum power points will diverge dramatically. As a result, cells connected in parallel cannot automatically maximize the power generation of each cell. Fortunately, this situation almost never happens in real applications.

The solar array temperature is generally even across the panel surface since irradiance across each cell surface changes continuously due to the movement of the panel or the changing of shadows. The temperature of cells directly exposed may be a few degrees higher than the partially shaded cells. In order to study the temperature effect on the power generation of different configurations, two sets of curves were calculated and plotted in FIG. 6. The lines with circle marks, representatively circle mark 612, from top to bottom, indicate the P-V curves at 300 K from 1000 W/m² to 100 W/m² (with a step change of 100 W/m²); the lines with star marks, representatively star mark 610, denote the P-V curves from 1000 W/m² to 100 W/m² with temperature changing from 318 K to 300 K (with a step change of 2 K). The standard deviation of the voltage values corresponding to the maximum power points at 320 K is 0.011; while the standard deviation of the voltage values corresponding to the maximum power points at the different temperatures is 0.007. Therefore, a small temperature difference (e.g., 20 K) is actually helpful to maximize the power generation of solar cells connected in parallel.

Based on the above analysis, the present subject matter provides an optimum array configuration for low voltage PV applications, i.e. a solar array with a very limited number of cells in series and multiple strings in parallel. A power electronics converter is used to regulate the voltage to a designed level as well as to serve as the Maximum Power Point Tracker (MPPT). The most effective way to maximize the power generation of each cell is to connect all of the cells in parallel. However, the terminal voltage of the solar array is very low (equal to the voltage of one cell, e.g., 0.4 V at the maximum power points), which increases the difficulty to boost the voltage to a desired level. As a tradeoff, a small number of cells (e.g., two or three cells) are connected in series with each cell having a small enough surface area so that the whole string can be assumed under uniform irradiance during most of the operation time. Of course, cells with too small a surface area will induce too many wiring lines to connect them into a solar panel, which in turn decreases the effective surface area and may increase weight. A practical way to avoid this is to estimate the light spot area for a given application and use it to determine the cell surface area.

Generally the terminal voltage developed directly from the solar array is too low to match the voltage requirements of most portable devices. It is advantageous, therefore, to use power electronics converters to boost the terminal voltage to desired levels. Advanced technologies, like the high-current, low-voltage power converters for CPUs in personal computers, can be applied here. It has been pointed out that, for a given silicon solar cell, the terminal voltage corresponding to the maximum power points is almost independent of the irradiance level and insensitive to temperature variation (e.g., 20 K difference). Thus, the terminal voltages corresponding to the maximum power points at different temperatures can be determined and then used as reference values by the power converter to control the solar array terminal voltage (also the input voltage of the power converter). By controlling the solar array terminal voltage to follow the reference points, the maximum power generation of the solar panel at different temperatures is achieved. Therefore, it is easy to implement and cost-effective.

A more specific understanding of a first embodiment of the present subject matter maybe had with further reference to FIG. 2. FIG. 2 shows a block diagram showing an experimental solar power generation system according to the first embodiment of the present subject matter. In FIG. 2, reference numeral 100 indicates a solar array, reference numeral 110 an individual solar cell, and reference numeral 111 a solar cell string with three cells connected in series. An experimental solar array 100 was constructed of 81 silicon cells with three cells in series then twenty seven strings in parallel, and each cell measured 2 cm by 2 cm resulting in a surface area of 4 cm². Solar array 100 yielded an open circuit voltage around 1.5 V which was then converted to 3.3 V by boost converter 120. Two cells of ultra-capacitors were connected in series and served as the energy repository 130 in which each ultra-capacitor cell had a capacity of 350 F.

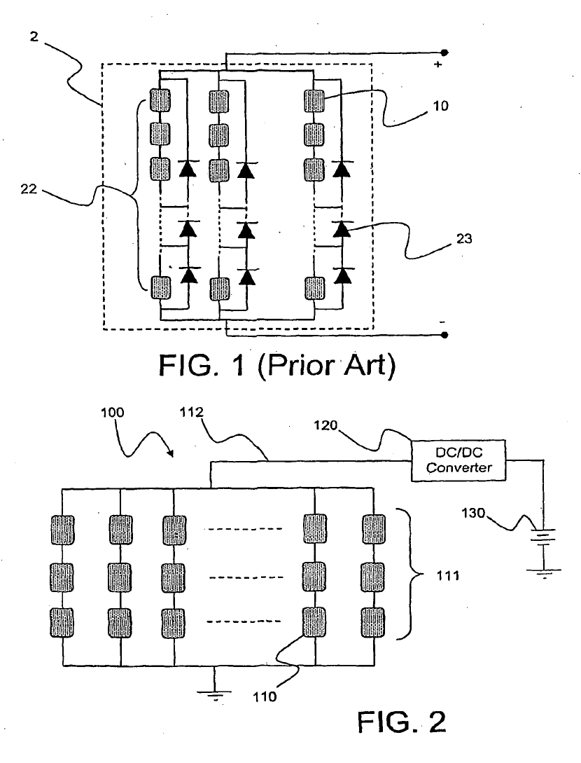

For comparison, another solar array using a conventional configuration similar to that illustrated in FIG. 1 was also built. The comparison conventional solar array was constructed of eighty cells with twenty cells in series then four strings in parallel, and every five cells in series was bypassed by a diode. This solar array yielded an open circuit voltage around 10 V which was then converted to 3.3 V by a buck converter. Two cells of ultra-capacitors were connected in series and served as the energy repository in which each ultra-capacitor cell had a capacity of 350 F.

Both of the solar system prototypes were tested in lab conditions and in an outdoor environment. At the beginning and the end of each experimental test, the terminal voltages of the ultra-capacitor packs were measured, which were used to calculate the energy charged into the ultra-capacitor and the average power of each solar panel. The initial voltage of the ultra-capacitor pack was pre-charged to about 2.2 V to simulate two depleted secondary battery cells (e.g., NiMH or NiCd batteries) in general applications. Seven experimental tests in total were conducted, in which the first five tests were done out-of-doors and the last two were done in the laboratory. In each test, the power generated by the first embodiment of the present subject matter was first normalized to 100% and then it was used to calculate the relative power generated by the solar array using the conventional configuration.

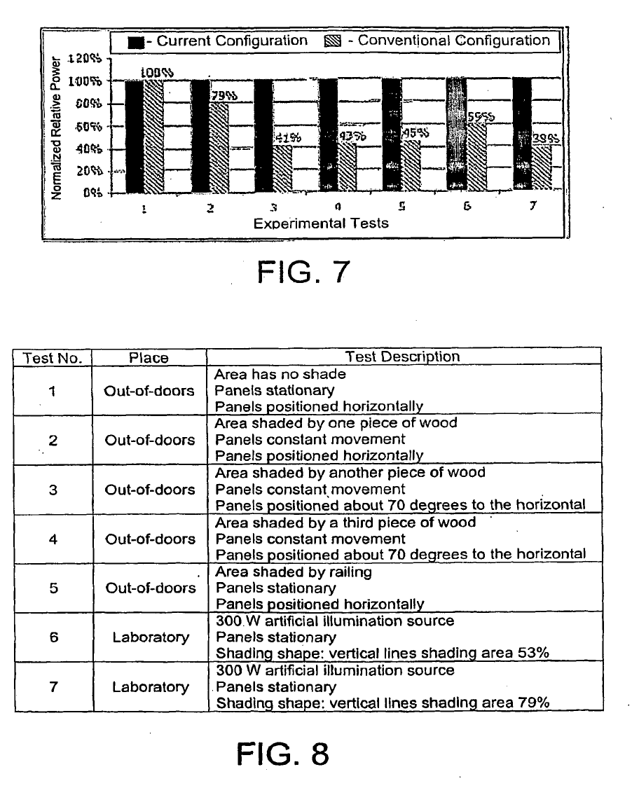

With reference no to FIG. 7, it can be seen that the experimental solar array using the configuration provided in the present subject matter (designated “current configuration”) has better performance and its power generation capability is greater, typically by a factor of 2 at partially shaded conditions than the “conventional configuration” representing the comparison solar array constructed in the manner of FIG. 1. For reference purposes, FIG. 8 lists the descriptions of test conditions. It is noted here that, in this first embodiment, both of the power converters are commercialized products for general battery charging applications and the integrated control algorithms were not designed to track the maximum power point of solar arrays.

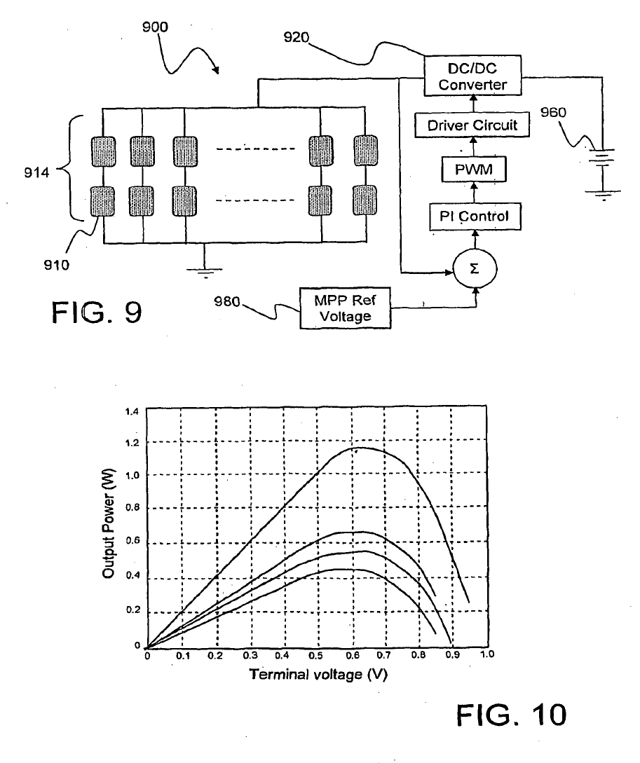

With reference now to FIG. 9, a second embodiment of the present subject matter will be described that integrates the Maximum Power Point Tracker (MPPT) previously mentioned into the power converter control. FIG. 9 illustrates a block diagram showing an experimental solar power generation system according to the second embodiment of the present subject matter. In FIG. 9, reference numeral 900 indicates a solar array, reference numeral 910 an individual solar cell, and reference numeral 914 a solar cell string with two cells 910 connected in series.

Solar array 900 was constructed of 80 silicon cells with 2 cells in series then 40 strings in parallel, and each cell measured 2 cm by 2 cm resulting in a surface area of 4 cm². Solar array 900 yielded an open circuit voltage around 1.1 V. Two cells of AA size Ni—Cd batteries were connected in series and served as the energy repository 960. A maximum power point tracking algorithm was implemented through a proportional integral (PI) controller by comparing and regulating the solar array output voltage to the MPP reference voltages 980.

A prototype of the solar array system constructed in accordance with the present subject matter was tested in laboratory as follows. A 300 W camera lamp was applied as the artificial illumination source and a pulse current load was connected to a battery stack. The pulse load profile had a regular period of 9 s with 6 s of high current demand 0.4 A and 3 s of low current demand 0.1 A. FIG. 10 shows the power generation of the solar array using different stationary shades. As may be noted from the graph, the terminal voltage corresponding to the maximum power points was 0.62 V. This voltage value was set as the MPP reference value 980 for the solar array 900 at room temperature.

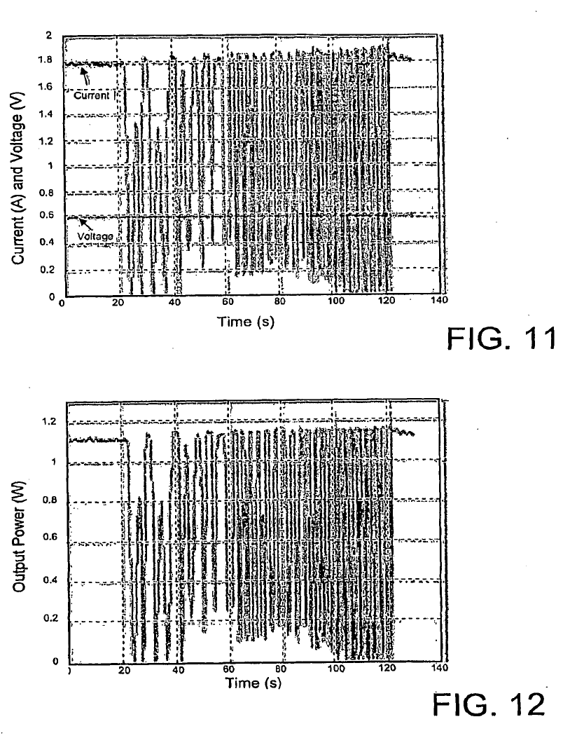

FIGS, 11 and 12 illustrate the dynamic performance of the solar array 900 during a 130 s experimental test. The illumination conditions during the test were quickly and continually changed by randomly shading the solar array surface. It can be seen that, in FIG. 11, the solar array output current changed significantly according to irradiance variations; while the solar array terminal voltage was controlled to be almost constant at 0.62 V. As may be seen FIG. 12, by controlling the solar array terminal voltage to follow prescribed reference values, the MPPT was implemented and the maximum power generation at different irradiance levels were obtained.

To further illustrate advantages obtained by way of the present subject matter, a virtual portable solar array system using detailed physical based models of a solar cell and diode were created in a Virtual Test Bed (VTB) computational environment. The solar cell model was built based on coupled multi-physics equations including photovoltaic process that converts light into electricity, electro-thermal process that turns some of electrical energy into heat (due to resistive heating and diffusion losses), direct heating due to infrared absorption and recombination loss, and cooling due to conduction, convection and radiation as described by S. Liu and R. A. Dougal, “Dynamic Multi-physics Model for Solar Array”, IEEE Transactions on Energy Conversion, Vol. 17, No. 2, pp. 285-294, June 2002. The physics-based diode model includes the transient characteristics of diode such as forward overshoot and reverse recovery. It also contains the effects of emitter recombination and junction capacitance.

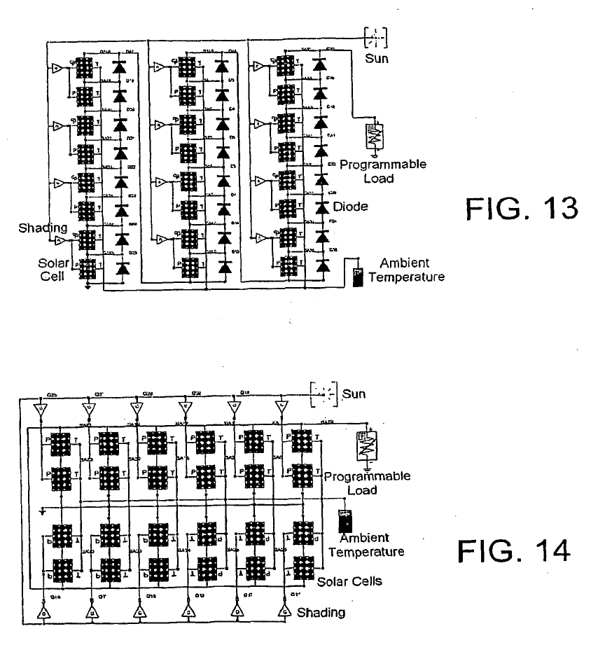

FIGS. 13 and 14 schematically illustrate the solar array system in the VTB for two different cell configurations. Each of the solar arrays contains 24 cells in total with an active area of 25 cm² per cell. In Configuration I, as illustrated in FIG. 13, all the cells are connected in series with each cell bypassed by a diode. The solar array is partially shaded through the “Shading” models with assumption that every two cells are under uniform illumination. A programmable load is connected to the solar array to find out the maximum power value that the solar array can supply under a given illumination. All the cells are thermally connected to an “Ambient Temperature” block. In Configuration II, as illustrated in FIG. 14 and modeled in accordance with the present subject matter, the solar array is configured as two cells in series to form a string of cells and then 12 strings in parallel.

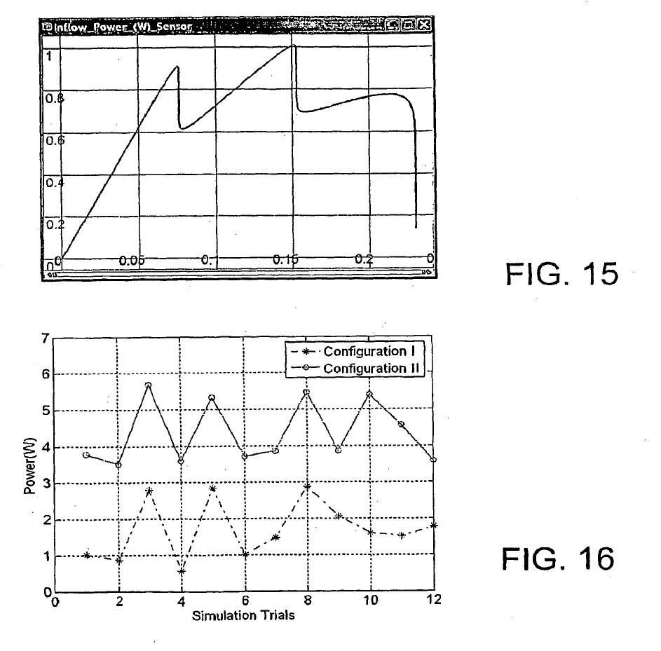

To test the power value for the two configurations, both configurations were simulated for 12 times. For each simulation, a different illumination was randomly generated using the “Shading” model, which was applied to both configurations in order to compare the power generations. FIG. 15 shows the power generation of the solar array as a function of the load current during one simulation for Configuration I. As can be seen, there exist three peak power points with the values of 0.91 W, 1.0 W and 0.77 W, respectively. It is noted that the second peak, 1.0 W, is the global maximum power point at the given illumination.

As well known, the original idea of bypass diodes is to isolate the individual shaded cells and thus allow most of the cells to generate power. However, in portable solar arrays, quite a fraction of cells may be partially shaded. As a result, there exists more than one peak power point. Clearly, some of the energy is not collected due to bypass diodes, thus Configuration I can not be used to operate the system at the global maximum power point.

In Configuration II, in accordance with the present subject matter, cells are connected in parallel. For different illumination conditions, the voltage for MPP of each cell is slightly different. Thus, using the parallel configuration with the same terminal voltage causes a slight deviation from the MPP of the entire array. Even so, cells connected in parallel can almost make the full usage of every cell because Configuration II essentially maximizes the power of every cell. For example, simulation results demonstrate that, at the temperature of 300 K, the maximum powers for one cell of 25 cm² are 0.2903 W and 0.0305 W corresponding to the irradiances of 850 W/m² and 100 W/M², respectively. The maximum power for two cells in parallel is 0.3159 W, which is 98.47% of the sum of the two separate cells (0.2903+0.0305=0.3208 W).

FIG. 16 illustrates the comparison of the maximum power generated by the two configurations for 12 simulations. The average value of the maximum power points for Configuration I is 1.7 W, whereas for Configuration II it is 4.37 W. This is a 157% increase in power generation with the same number of cells under the same illumination conditions.

One problem with Configuration II is its possible low terminal voltage, around 1.0 V. In order for the power source to match the voltage requirements of most portable devices it may be necessary to use power electronics converters to boost the terminal voltage to the desired level. The advanced technologies, like the high-current-low-voltage power converters for CPUs in PCs as previously discussed may be applied to achieve such a boost to the terminal voltage. In addition, a cascade structure corresponding to several subsystems of Configuration II constructed in accordance with the present subject matter can be used through appropriate converter connection to boost the output voltage.

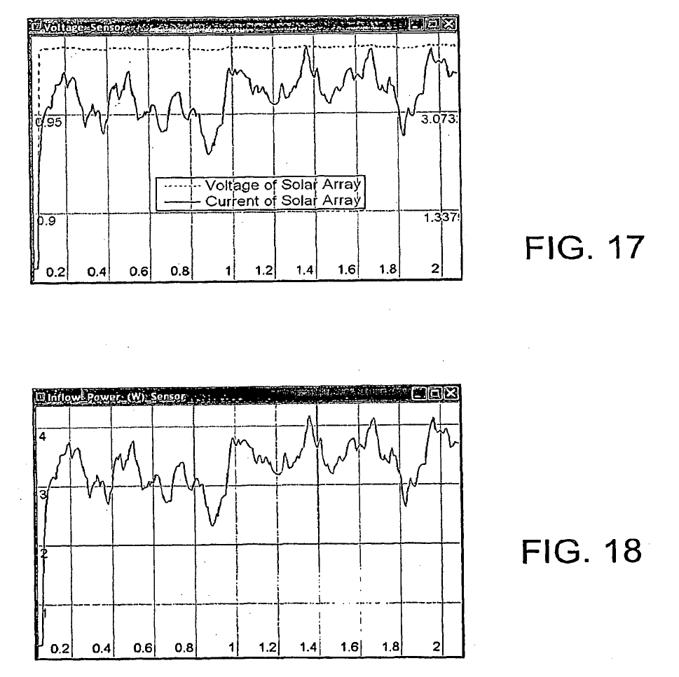

The system of Configuration II was simulated to study the performance. In the simulation, each of the twelve paralleled strings (each string has a pair of cells in series) was subject to different irradiances randomly varying from 50 W/m² to 850 W/m². FIG. 17 illustrates the voltage and the current of the solar array during the simulation. FIG. 18 shows the power generation of the solar array. From the simulation results, it can be seen that the portable solar array using optimum configurations can maximize the power generation even under the conditions of complex illumination conditions.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A solar power generation apparatus for providing operating power for a desired application, the desired application having a predetermined operating voltage level requirement, comprising:
an array of solar cells comprising a first number of solar cells electrically connected in series to form a string of solar cells and a second number of said strings of solar cells connected in parallel to form the array, said array capable of producing a first output voltage level; and
a power converter coupled to said array, said power converter configured to boost the first output voltage level to a second output voltage level higher than said first output voltage level,
wherein the first output voltage level is insufficient to meet the desired application operating voltage level requirement.

2. The solar power generation apparatus of claim 1, wherein each string of solar cells has a surface area such that each string of solar cells is individually subjected to substantially uniform irradiance during operation.

3. The solar power generation apparatus of claim 1, wherein each string of solar cells consists of the same number of solar cells connected in series.

4. The solar power generation apparatus of claim 3, wherein each string of solar cells consists of two solar cells connected in series.

5. The solar power generation apparatus of claim 3, wherein each string of solar cells consists of three solar cells connected in series.

6. The solar power generation apparatus of claim 1, further comprising:
a maximum power point controller coupled to said power converter, said controller configured to monitor said first output voltage level and control said power converter based on a predetermined reference voltage value.

7. The solar power generation apparatus of claim 6, wherein the predetermined reference value is determined based on the construction material of the solar cells and the array operating temperature.

8. A method of providing operating power for a desired application, comprising:
providing a solar array;
coupling a power converter to said solar array; and
operating the power converter to provide an increased voltage level from the solar array to provide operating power to the desired application.

9. The method of claim 8, wherein providing a solar array comprises:
providing a plurality of strings of solar cells comprising a first number of solar cells electrically connected in series; and
connecting the plurality of strings in parallel.

10. The method of claim 9, wherein providing a plurality of strings of solar cells comprises:
providing a plurality of strings of three solar cells electrically connected in series.

11. The method of claim 8, further comprising:
monitoring an output level of the solar array; and
controlling the power converter based on the output level and a reference level.

12. The method of claim 11, further comprising:
selecting a reference level based on the operating temperature of the solar array.

13. The method of claim 11, further comprising:
selecting a reference level based on the construction material of the solar cells.

14. The method of claim 12, further comprising:
selecting a reference level based on the construction material of the solar cells.
